(19) United States
(12) Patent Application Publication
(10) Pub. No.: US 2007/0056513 A1
(43) Pub. Date: Mar. 15, 2007

(54) System for situ photoresist thickness characterizaton

(76) Inventors: Paul D. Shirley, Meridian, ID (US); Craig Hickman, Boise, ID (US)

Correspondence Address: TRASK BRITT, P.C./ MICRON TECHNOLOGY, P.O. BOX 2550, SALT LAKE CITY, UT, 84110, US

(21) Appl. No.: 11/599,221

(22) Filed: Nov. 13, 2006

Related U.S. Application Data
(62) Division of application No. 10/747,542, filed on Dec. 29, 2003.

(51) Int. Cl. B05C 11/00; B05C 13/02; C23C 16/52; B05D 3/12

(52) U.S. Cl. 118/712; 118/52; 427/240; 427/8

(57) ABSTRACT

An in situ photoresist thickness characterization process and apparatus characterizes a photoresist process used for processing a semiconductor wafer. Photoresist is dispensed on a spinning semiconductor wafer as part of the characterization process. The thickness of the photoresist is monitored at a plurality of locations on the spinning semiconductor wafer at specific time intervals while the photoresist flows across the wafer. The thicknesses are recorded from the plurality of locations and for the specific time intervals for use in making process control decisions. A semiconductor process for coating a semiconductor wafer according to characteristics derived from the characterization process deposits photoresist on a wafer and spin-coats the wafer according to the photoresist process characterization process.

### CROSS-REFERENCE TO RELATED APPLICATION

This application is a divisional of application Ser. No. 10/747,542, filed Dec. 29, 2003, pending.

### BACKGROUND OF THE INVENTION

1. Field of the Invention

The present invention relates to a semiconductor device fabrication process and, more particularly, to characterization of a photoresist process in a semiconductor coating process.

2. State of the Art

Semiconductor processing for forming integrated circuits requires a series of processing steps. These processing steps include the deposition and patterning of a variety of material layers. The material layers are typically patterned using a photolithographic process, which uses a patterned photoresist layer as an etch mask that is patterned over the material layer. The photoresist layer is formed by first depositing liquid photoresist onto the semiconductor wafer and then spin-coating the wafer to the desired thickness. The photoresist is dried or baked and subjected to light through a photomask or reticle, and then developed to form a photoresist etch mask.

As integrated circuit dimensions decrease, the uniformity of semiconductor processes becomes increasingly important. Photolithography processing equipment is used for various types of semiconductor wafers and processes are set up and taken down as semiconductor equipment is reused over various processes and for various specifications. Photolithography process set up currently is a tedious, time-consuming chore. The photoresist pump must be primed, a wafer must be coated with photoresist, and then the coated wafer must be baked. The wafer coating thickness is then measured at a random sampling of points across the wafer. Known measuring equipment requires a significant amount of time to measure each point.

Defective coatings may be identified when the average coating thickness measurement is beyond the range of process specifications, or when the standard deviation of thickness measurements around the wafer is larger than a specific tolerance. Once a process parameter is found to be outside of the process specifications, the coating process must be adjusted, another wafer must be coated and baked, and the coating must be manually rechecked until the photoresist thickness is within the process specifications. As a result, a substantial delay often occurs before production processing may begin.

Optimization of photoresist processes has conventionally been time-consuming and conducted on an ad hoc basis. A series of test wafers is coated at various spin rates and for various times. This series of test wafers is then measured and processes are adjusted accordingly. A series of spin curves is generated based on the spin rate vs. the thickness information. The operator of the process then makes several adjustments to obtain the best possible uniformity for the target thickness. Such a trial and error approach requires the running of several wafers and such processing can take anywhere from 1-6 hours per thickness and still not guarantee an optimal setup. For example, the best possible uniformity for a given photoresist thickness when the wafer is spun out for 5 seconds may be a variation of 25 Angstroms, but the optimal uniformity for the same thickness might be achieved at 4.2 second with a slightly lower spin time and yield a variation of 15 Angstroms.

Conventionally, each of the data points on a spin curve is derived from a separate wafer and then recorded for future reference. Due to inherent processing variations, when a subsequent process is set up, a spin curve is referenced for the best possible candidate and then a process wafer is run to identify small operator adjustments. It would be advantageous to obtain additional data points across a spin curve without processing specific wafers for each data point.

### BRIEF SUMMARY OF THE INVENTION

An in situ photoresist thickness characterization process and apparatus is provided. In one embodiment, a method is provided for characterizing a photoresist process used for processing a semiconductor wafer. Photoresist is dispensed on a spinning semiconductor wafer as part of the characterization process. The thickness of the photoresist is monitored at a plurality of locations on the spinning semiconductor wafer and at specific time intervals while the photoresist flows across the wafer. The thicknesses are recorded from the plurality of locations and for the specific time intervals.

In another embodiment of the present invention, a photoresist process characterization system for performing the characterization method is provided. A photoresist dispenser controllably dispenses photoresist on the semiconductor wafer while a spinning system rotates the wafer at a specified spin rate. A thickness measurement apparatus monitors the thicknesses of the photoresist on the wafer at a plurality of locations and at specific time intervals while the photoresist flows across the semiconductor wafer.

In yet another embodiment of the present invention, a process for coating a semiconductor wafer according to characteristics derived from the characterization process is provided. Photoresist is deposited on a semiconductor wafer and the wafer is spin-coated according to a recipe derived from a photoresist process characterization system. The photoresist process characterization system includes a photoresist dispenser which controllably dispenses photoresist on the semiconductor wafer while a spinning system rotates the wafer at a specified spin rate. A thickness measurement system monitors the thicknesses of the photoresist on the wafer at a plurality of locations and at specific time intervals while the photoresist flows across the semiconductor wafer.

In yet a further embodiment of the present invention, a computer-readable medium having computer-executable instructions thereon for performing the method of characterizing a photoresist process is provided.

### BRIEF DESCRIPTION OF THE SEVERAL VIEWS OF THE DRAWINGS

In the drawings, which illustrate what is currently considered to be the best mode for carrying out the invention:

FIGS. 1A and 1B show an explanatory view of photoresist coating and the associated propagation of photoresist across a spinning wafer;

FIG. 2 is a flow chart of a method for characterizing a photoresist process, in accordance with an embodiment of the present invention;

FIG. 3 is a simplified block diagram of a photoresist process characterization system, in accordance with an embodiment of the present invention;

FIG. 4 is a detailed block diagram of a measurement system for characterizing a photoresist process, in accordance with an embodiment of the present invention;

FIG. 5 is a plotted chart of an exemplary derived set of data points obtained in accordance with an embodiment of the present invention;

FIG. 6 illustrates an example of a stored database with exemplary data derived and processed in accordance with an embodiment of the present invention; and

FIG. 7 is a simplified block diagram of a semiconductor process system configured to apply a recipe selected from the photoresist process characterization method, in accordance with an embodiment of the present invention.

### DETAILED DESCRIPTION OF THE INVENTION

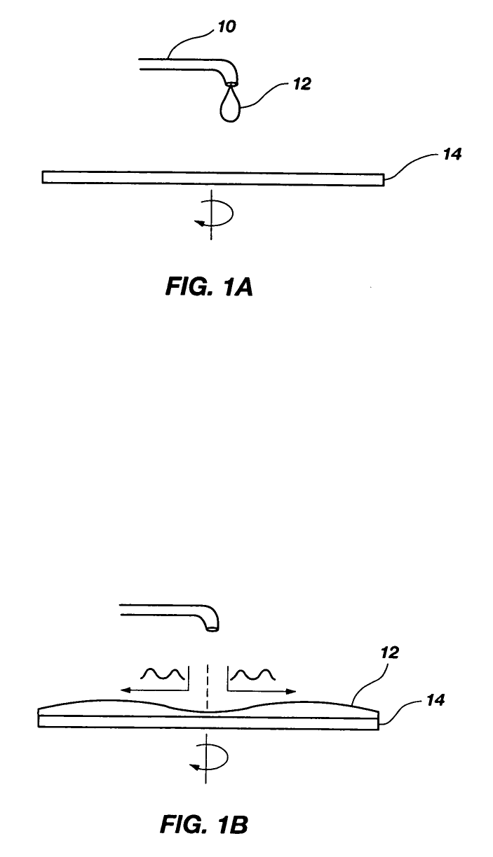

FIG. 1A is a perspective view of method for applying photoresist in a conventional manner to a semiconductor wafer. As illustrated, a photoresist dispenser 10 dispenses photoresist 12 onto a spinning semiconductor wafer 14, photoresist 12 then propagates out across the upper surface of semiconductor wafer 14 as a function of the centrifugal force associated with the spinning semiconductor wafer 14. Spin-coating fluid dynamics have been studied in some detail. While it would be desirable for the photoresist 12 to be propagated uniformly over the wafer, it is appreciated that photoresist 12 propagates in a somewhat irregular profile over time. Those of ordinary skill in the art appreciate that a photoresist layer during spin-coating undergoes some intermediate shapes. For example, at the start of spinning, a wave of photoresist is created that then moves toward the wafer edge. A corona state generally occurs next, in which the bulk of the photoresist on the wafer migrates out to the wafer edge to form a crown-like structure. Next, an appreciable portion of the photoresist is driven off the wafer, causing the wave and corona to disappear. Then, centrifugal force drives the remaining excess photoresist off the surface of the wafer.

Photoresist coating processes include several variables, values for which may be maintained as “recipes” for referencing and reuse. Conventionally, recipes for photoresist coating of a semiconductor wafer were derived from only a very few data points, since the generation of each data point required the processing of a separate wafer and many photoresist and process environment parameters contribute to the variations in possible photoresist processes. For example, different photoresists have different viscosities that affect the spin-coating process. Also, the vapor pressure of the solvent that is in the photoresist to assist in the coating process presents variations to the overall process.

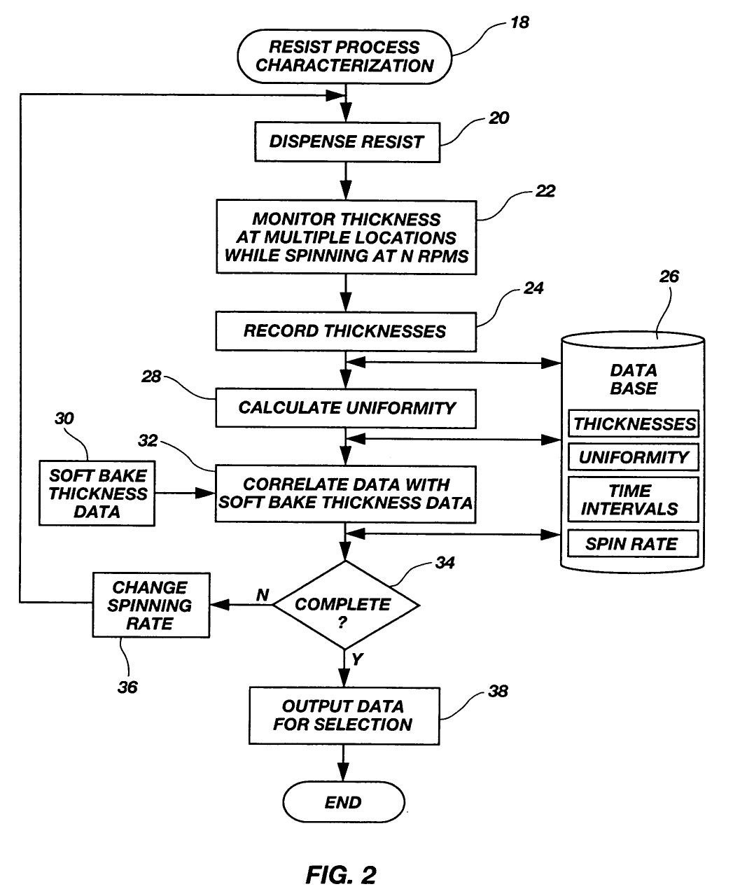

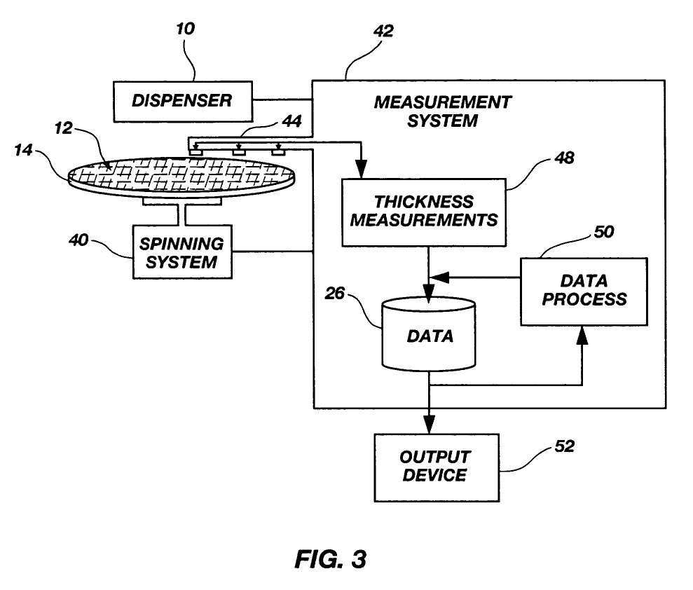

Reference to FIGS. 2 and 3 will be described herein concurrently. FIG. 2 is a method for characterizing a photoresist process, in accordance with an embodiment of the present invention and FIG. 3 is a photoresist process characterization system in accordance with an embodiment of the present invention. A photoresist process characterization method 18 results in the generation of spin curves which identify specific parameters of a photoresist process. In FIG. 2, photoresist is dispensed 20 onto a semiconductor wafer, as illustrated in FIG. 1. Photoresist is dispensed 20 by a photoresist dispenser 10, and dispensing may be accomplished by either flooding the entire semiconductor wafer 14 with photoresist 12 before beginning the spinning by spinning system 40 or by dispensing a smaller volume of photoresist at the center of the wafer and spinning at a predefined spin rate to produce a layer of photoresist 12 across the semiconductor wafer 14. Dispensing may also be performed according to static dispensing techniques where the wafer remains stationary during dispensing or, alternatively, according to dynamic dispensing techniques where the wafer rotates during dispensing. The amount and dispense rate calculations of the photoresist material is known and appreciated by those of ordinary skill in the art and is not further discussed herein.

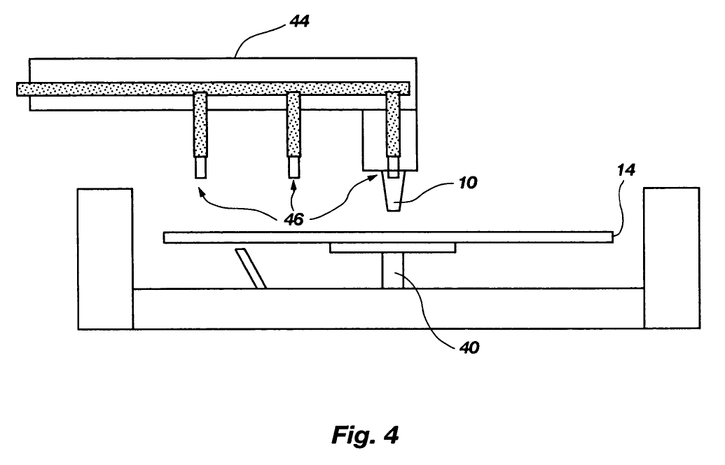

As the photoresist flows across the semiconductor wafer 14, the thickness is monitored 22 at multiple locations across the semiconductor wafer by measurement system 42. Measurement of the photoresist thickness at multiple locations is indicative of the flow and thickness uniformity across the wafer. Measurement system 42 is configured to provide concurrent multiple readings across the radius or diameter of the semiconductor wafer at specific time intervals while the photoresist is flowing outwardly during the spinning process. Various measurement techniques for measuring film thickness are contemplated. One exemplary measurement system 42 includes one or more forms of sensors 44 which may assume various configurations, one of which is a multihead reflectometer as illustrated in FIG. 4. Reflectometry utilizes reflection from light as it crosses an interface between two different materials. The fraction of light that is reflected by an interface is determined and, using mathematical equations known to those of ordinary skill in the art, the photoresist thickness may be derived.

In FIG. 4, sensors 44 may further include a plurality of measurement heads 46 which may be arranged along a radius of semiconductor wafer 14 and, in any case, may be arranged at different radial locations. The respective locations and placements of measurement heads 46 enable the measurement system 42 (FIG. 3) to monitor photoresist thickness at a plurality of locations on the semiconductor wafer. While three heads 46 are illustrated, more or less heads are also contemplated within the scope of the invention. Because of the dynamic flow of the photoresist across the wafer, it is desirable that the measurement system 42 be capable of rapid signal acquisition and analysis. By way of example and not limitation, a multihead reflectometer can include an in situ measurement system available from Tevet Process Control Technologies Ltd. of Yokneam Moshava, Israel.

As indicated in FIG. 2, the method records 24 the thickness measurements 48 across the wafer and stores them, for example, indexed by the specific measuring time intervals in a database 26. Returning to the method of FIG. 2, other characteristics may be derived from the recorded thickness measurements. One such characteristic of interest is the uniformity of the photoresist layer, which is calculated 28 from the measured thicknesses at the plurality of locations on the semiconductor wafer. Uniformity relates to the relative variations between each of the measured thicknesses at a specific time interval. Uniformity may be calculated using various statistical methods including the variance between the smallest and largest thickness measurements. Those of ordinary skill in the art appreciate that a smaller value of uniformity, or in other words a smaller variation of thicknesses, is preferable to accommodate more consistent processing at the various locations across the semiconductor wafer. The uniformity calculations may be further stored in database 26 to be retrieved at a later time to form a spin curve, plot multiple spin curves or to form tabular data. The calculation of uniformity values as well as other processing is performed in a data process 50 of FIG. 3 configured to perform statistical calculations.

In order to more accurately calibrate the thickness data and uniformity data stored in database 26, one or more actual test semiconductor wafers corresponding to the data in the database may undergo further physical processing. The resulting semiconductor wafer is further measured to determine actual finished process thickness measurement data which may then be correlated 32 with the thickness measurement data stored in the database 26. Once semiconductor wafers are coated with photoresist, the next processing step includes a soft-bake step which accomplishes several important purposes, including driving off the solvent from the spun-on photoresist as well as providing adhesion and annealing benefits. Once the photoresist is soft-baked, characterization tests are performed on the photoresist thickness to determine actual soft-baked thickness measurement data 30 which is then correlated 32 to calibrate or improve the accuracy of thickness measurement data and uniformity data within database 26.

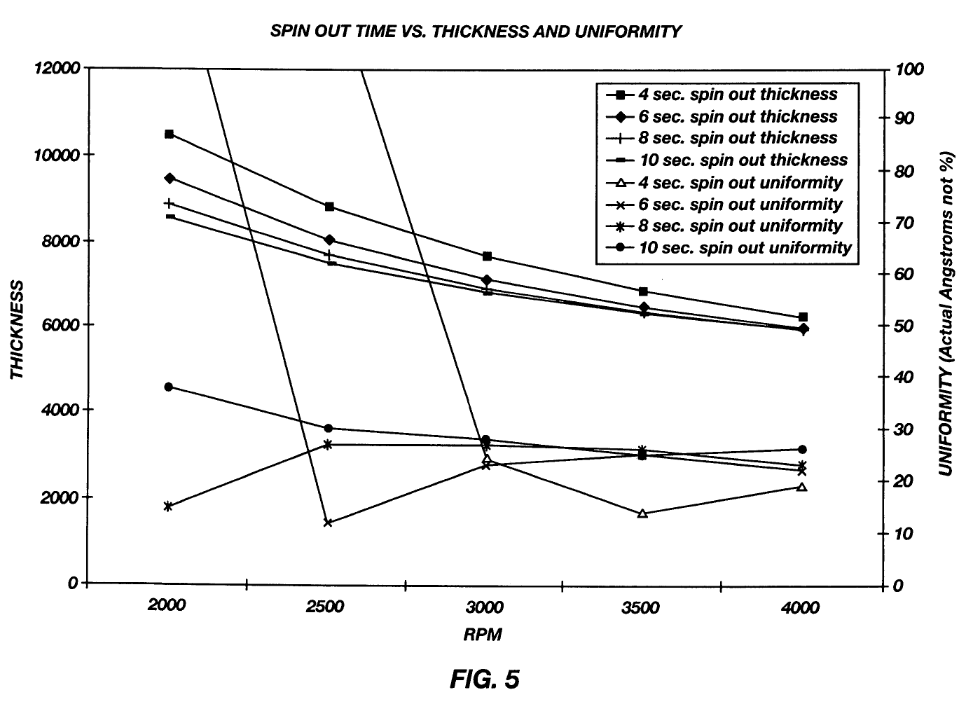

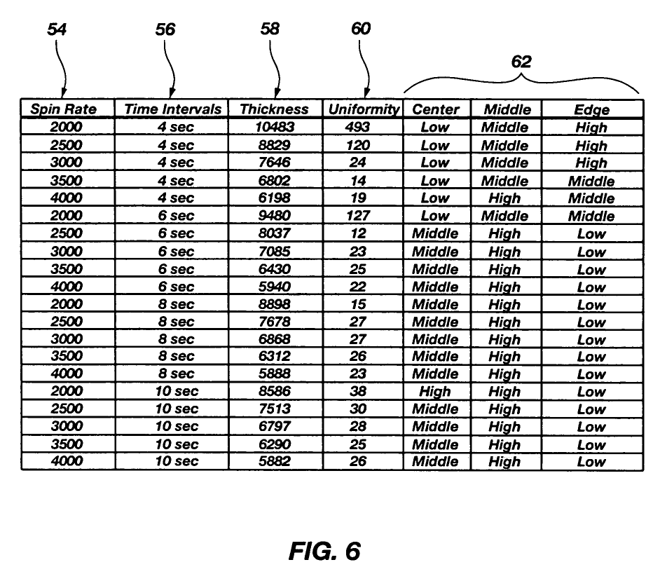

The present method further contemplates the generation of multiple spin curves at multiple spin rates. A query 34 determines whether further spin curves are desired and when such curves are desired, the spinning rate is changed 36 to another desired spin rate and processing returns with a new spin rate. When the data for the desired spin curves are derived, data from database 26 is output 38 for selection or utilization by either a manual operator or an automated operator for making the desired selection for the process setup. An output device 52 (FIG. 3) generates plotted outputs such as those representative in FIGS. 5-6.

FIG. 5 is a plot of thickness measurements derived from the method and system described with reference to FIGS. 2 and 3. In FIG. 5, thickness measurements are plotted for specific time intervals at specific spin rates of, for example, 2,000 rpm, 2,500 rpm, 3,000 rpm, 3,500 rpm and 4,000 rpm. The various time intervals for each of these spinning rates are further illustrated as, for example, 4 seconds, 6 seconds, 8 seconds and 10 seconds. Uniformity, as calculated, may also be superimposed or separately plotted and is illustrated at the same respective time intervals. The data may them be grouped using various preferred interpretation approaches. In FIG. 5, each of the time interval data points is graphed to illustrate the spin-out thicknesses at various spinning rates as well as the uniformity at the respective time intervals. Once plotted, a manual process operator or an automated operator may reference the specific plots or underlying data and determine a specific recipe of the desired spin-out spin rate (e.g., r.p.m.) and associated spin-out time for a preferred thickness and uniformity.

FIG. 6 illustrates an exemplary arrangement of data stored and calculated for referencing and plotting within database 26 (FIG. 2). As illustrated, various spin speeds or rates 54 may be performed through successive traversals of the method of FIG. 2 with the various time intervals 56 referenced for the recording of thickness measurements 58 which may be a weighted single thickness entry or the recordation of multiple thickness measurements. As uniformity is also a desired characteristic, the uniformity 60, as described, is calculated and stored for determining a preferred spin rate 54 and a spin-out time from the time interval 56. Other data or information 62 may also be calculated which identifies relative ranges of the thickness across, for example, the plurality of sensors. The stored data information may be utilized either from tabular form as is illustrated with reference to FIG. 6 or by graphical depiction as illustrated with reference to FIG. 5.

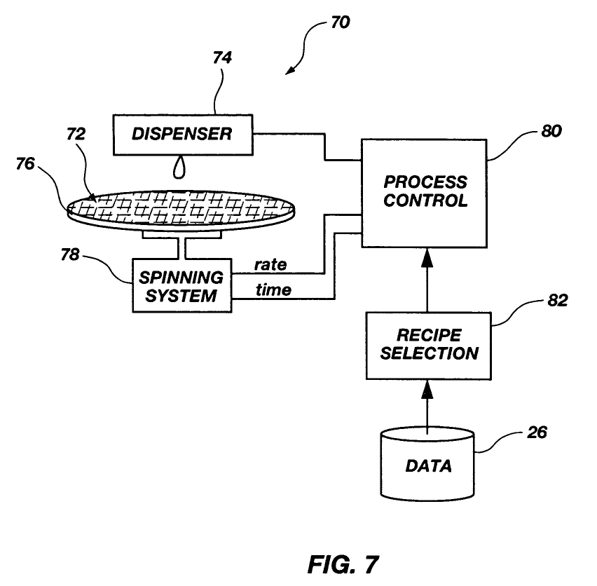

FIG. 7 is a simplified block diagram of a semiconductor process system configured to apply a recipe selected from the photoresist process characterization method, in accordance with an embodiment of the present invention. A semiconductor process system 70 performs a photoresist coating process by selecting a recipe or process parameters including spin rate, time interval, and other control parameters. Specific recipe options are obtained from database 26 with a manual or automated selection process 82 which selects a specific combination of process parameters. A process control 80 then controls a photoresist dispenser 74 and a spinning system 78 for forming a photoresist layer 72 on semiconductor wafer 76.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention includes all modifications, equivalents, and alternatives falling within the spirit and scope of the invention as defined by the following appended claims.

What is claimed is:

1. A photoresist process characterization system, comprising:
a photoresist dispenser to controllably dispense photoresist on a semiconductor wafer;
a spinning system configured to spin the semiconductor wafer at a specified spin rate; and
a thickness measurement system configured to monitor thicknesses at a plurality of locations and at specific time intervals of the photoresist on the semiconductor wafer while the photoresist flows across the semiconductor wafer.

2. The system of claim 1, wherein the thickness measurement system further comprises a database for storing the thicknesses at a plurality of spin rates.

3. The system of claim 1, wherein the thickness measurement system further comprises a process for computing a uniformity of the thicknesses across the plurality of locations.

4. The system of claim 1, further comprising an output device for presenting data for selection during manufacturing of semiconductor wafers.

5. The system of claim 1, wherein the spinning system is configurable to rotate at various spin rates.

6. The system of claim 1, wherein the thickness measurement system comprises a reflectometer for measuring the thicknesses.

7. The system of claim 6, wherein the reflectometer includes a plurality of measurement heads corresponding to the plurality of locations distributed about a radius of the semiconductor wafer.

8. The semiconductor process of claim 3, wherein the uniformity is a weighted function of a portion of the plurality of thickness.

9. The semiconductor process of claim 3, wherein the uniformity is displayed as a graphical plot.

10. The semiconductor process of claim 3, wherein the uniformity is displayed as tubular data.
